(19) United States
(12) Patent Application Publication
(10) Pub. No.: US 2026/0190447 A1
(43) Pub. Date: Jul. 2, 2026

(54) HIGH STRESS SIGE EPI GROWTH USING THE SIDEWALL OF FORKSHEET TRANSISTORS

(71) Applicant: Samsung Electronics Co., Ltd., Suwon-si (KR)

(72) Inventors: Jongchol Kim, Santa Clara, CA (US); Mehdi Saremi, Danville, CA (US); Rebecca Park, Mountain View, CA (US); Aravindh Kumar, Mountain View, CA (US); Muhammed Ahosan Ul Karim, San Jose, CA (US); Harsono Simka, Saratoga, CA (US)

(21) Appl. No.: 19/216,319

(22) Filed: May 22, 2025

Related U.S. Application Data
(60) Provisional application No. 63/740,249, filed on Dec. 30, 2024.

(51) Int. Cl. H10D 84/01; H10D 84/85

(52) U.S. Cl. CPC H10D 84/017; H10D 84/0188; H10D 84/852

(57) ABSTRACT

A method of manufacturing a forksheet field-effect transistor (FSFET) includes exposing a stack of alternating silicon layers and silicon-germanium (SiGe) layers in source/drain regions of the FSFET between a pair of outer spacers; selectively removing the SiGe layers in the source/drain regions of the FSFET to form voids; depositing an insulator in the voids previously occupied by the SiGe layers; and partially etching the insulator. A portion of the insulator remains between each of the silicon layers following the partially etching. The method also includes partially etching the silicon layers. A residual portion of the silicon layers remains following the partially etching. The method also includes laterally epitaxially growing the source/drain regions of the FSFET from the residual portion of silicon layers. The residual portion of the silicon layers is a seed for the laterally epitaxially growing the source/drain regions.

### CROSS-REFERENCE TO RELATED APPLICATION(S)

The present application claims priority to and the benefit of U.S. Provisional Application No. 63/740,249, filed Dec. 30, 2024, the entire content of which is incorporated herein by reference.

### BACKGROUND

### 1. Field

The present disclosure relates to forksheet field-effect transistors (FETs) and methods of manufacturing forksheet FETs.

### 2. Description of the Related Art

Forksheet field-effect transistors (FSFETs) include a dielectric wall between the n-channel metal-oxide semiconductor (NMOS) and the p-channel metal-oxide semiconductor (PMOS) devices. The dielectric wall enables scaling by reducing the spacing between the NMOS and PMOS devices, which improves performance, increases energy efficiency, and reduces cell area compared to related art nanosheet FETs.

High channel stress and low parasitic capacitance are important for the performance of FSFETs. Inner spacers may be provided in the FSFET to reduce parasitic capacitance. However, in related art methods of manufacturing a FSFET, the source/drain regions are formed by a discontinuous epitaxial growth process due to the presence of the inner spacers, which results in stacking faults and dislocations in the source/drain regions. That is, due to the presence of the inner spacers, during related art manufacturing, epitaxial growth of the source/drain regions occurs discontinuously from multiple fronts, which meet and form dislocations and a stacking fault in the vertical direction. These vertical stacking faults cause the channel stress to vanish or at least substantially decrease, which negatively impacts the performance of the FSFET. Accordingly, related art FSFETs may not have both high channel stress and low parasitic capacitance.

The above information disclosed in this Background section is only for enhancement of understanding of the background of the invention and therefore it may contain information that does not constitute prior art.

### SUMMARY

The present disclosure relates to various embodiments of a method of manufacturing a forksheet field-effect transistor (FSFET). In one embodiment, the method exposing a stack of alternating silicon layers and silicon-germanium (SiGe) layers in source/drain regions of the FSFET between a pair of outer spacers; selectively removing the SiGe layers in the source/drain regions of the FSFET to form voids; depositing an insulator in the voids previously occupied by the SiGe layers; partially etching the insulator such that a portion of the insulator remains between each of the silicon layers following the partial etching; partially etching the silicon layers such that a residual portion of the silicon layers remains following the partial etching; and laterally epitaxially growing the source/drain regions of the FSFET from the residual portion of silicon layers. The residual portion of the silicon layers are a seed for the lateral epitaxial growth of the source/drain regions.

Depositing may include isotropically depositing the insulator.

The partial etching may include isotropically etching the insulator.

The source/drain regions may be free from a vertical stacking fault.

The source/drain regions may include a horizontal stacking fault.

The source/drain may be formed continuously during the lateral epitaxial growth of the source/drain regions.

Laterally epitaxially growing the source/drain regions may include epitaxially growing the source/drain regions from three different faces of the residual portion of the silicon layers.

The three different faces may include a first face of the residual portion of the silicon layers between the insulator, a second face of the residual portion of the silicon layers along a first outer spacer of the pair of outer spacers, and a third face of the residual portion of the silicon layers along a second outer spacer of the pair of outer spacers.

In one embodiment, the method includes forming a stack of alternating silicon layers and silicon-germanium (SiGe) layers on a substrate; forming gates on the stack of alternating silicon layers and SiGe layers; forming outer spacers on the stack of alternating silicon layers and SiGe layers; forming a liner oxide layer along a lengthwise direction of the stack of alternating Si layers and SiGe layers; forming a sidewall on the liner oxide layer; selectively removing the SiGe layers in source/drain regions of the FSFET to form voids; depositing an insulator in the voids previously occupied by the SiGe layers; partially etching the insulator such that a portion of the insulator remains between each of the silicon layers following the partial etching; partially etching the silicon layers such that a residual portion of the silicon layers remains following the partial etching; and laterally epitaxially growing the source/drain regions of the FSFET from the residual portion of the silicon layers. The residual portion of the silicon layers is a seed for the lateral epitaxial growth of the source/drain regions.

The present disclosure also relates to various embodiments of a forksheet field-effect transistor (FSFET). In one embodiment, the FSFET includes a substrate; an n-channel metal-oxide semiconductor (NMOS) transistor on the substrate; a p-channel metal-oxide semiconductor (PMOS) transistor on the substrate; and a dielectric wall separating the PMOS transistor from the NMOS transistor. Each of the NMOS transistor and the PMOS transistor includes stacked nanosheet channel regions, source/drain regions at opposite ends of the nanosheet channel regions, and a gate on the nanosheet channel regions. The source/drain regions are substantially free from a vertical stacking fault.

The source/drain regions may include a horizontal stacking fault.

The PMOS transistor and the NMOS transistor may each include a pair of outer spacers.

The dielectric wall may include a sidewall and a liner oxide layer on the sidewall.

The present disclosure also relates to various embodiments of an electronic device including a forksheet field-effect transistor (FSFET). The electronic device may be a memory, an application specific integrated circuit (ASIC), a central processing unit (CPU), a field programmable gate array (FPGA), or a graphics processing unit (GPU).

This summary is provided to introduce a selection of concepts that are further described below in the detailed description. This summary is not intended to identify key or essential features of the claimed subject matter, nor is it intended to be used in limiting the scope of the claimed subject matter. One or more of the described features may be combined with one or more other described features to provide a workable method or device.

### BRIEF DESCRIPTION OF THE DRAWINGS

The features and advantages of embodiments of the present disclosure will be better understood by reference to the following detailed description when considered in conjunction with the accompanying figures. In the figures, like reference numerals are used throughout the figures to reference like features and components. The figures are not necessarily drawn to scale.

FIG. 1 is a forksheet field-effect transistor (FET) according to one embodiment of the present disclosure;

FIG. 2 is a flowchart illustrating tasks of a method of manufacturing a forksheet FET according to one embodiment of the present disclosure;

FIGS. 3A-3L depict the structure of a forksheet FET during a method of manufacturing the forksheet FET according to one embodiment of the present disclosure;

FIG. 4 is a graph comparing the channel stress loss due to a horizontal fault in the source/drain region, a vertical fault in the source/drain region, and no fault in the source/drain region, according to one embodiment of the present disclosure;

FIGS. 5A-5C depict models of a FSFET having no defect in the source/drain region, a FSFET having horizontal (lateral) defects in the source/drain region that are parallel to the Lgate (Lch), and a FSFET having vertical defects in the source/drain region that are normal (perpendicular) to the Lgate (Lch), respectively, that are utilized to generate the graph in FIG. 4; and

FIG. 6 depicts an electronic device including a forksheet field-effect transistor (FSFET) according to one embodiment of the present disclosure.

### DETAILED DESCRIPTION

The present disclosure relates to various embodiments of a forksheet field-effect transistor (FSFET) and methods of manufacturing the FSFET. During the method of manufacturing, residual silicon on the outer spacer is utilized as a seed for the epitaxial growth of the source/drain regions, which eliminates (or at least mitigates) the formation of vertical faults in the source/drain regions that would otherwise reduce channel stress and thereby negatively impact performance of the forksheet FET. In this manner, the FSFETs manufacturing according to the methods of the present disclosure have both high channel stress and low parasitic capacitance.

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The advancement of semiconductor technology continues to drive the need for transistor architectures that support increased device density, enhanced performance, and reduced power consumption at progressively smaller technology nodes. As process geometries scale, transistor designs incorporating gate structures that provide improved electrostatic control over the channel region may be utilized to address challenges associated with short-channel effects, leakage currents, and overall device reliability.

Transistor architectures utilized stacked channel structures and gate-all-around configurations may be utilized to facilitate improved control and scalability. In certain designs, isolation features may be positioned between adjacent devices to enable tighter integration of complementary transistors while maintaining electrical isolation and optimizing gate pitch.

As semiconductor devices evolve toward more advanced nodes, various design considerations arise, including minimizing or reducing parasitic capacitance, ensuring precise gate alignment, managing variability in channel structures, and simplifying fabrication processes.

Aspects of some embodiments of the present disclosure relate to a forksheet field-effect transistor (FSFET), which is a transistor architecture that includes vertically stacked semiconductor channel structures and agate electrode that surrounds the channels to provide enhanced electrostatic control. A dielectric isolation feature may be positioned between adjacent transistors to facilitate reduced gate pitch and improved device integration. A FSFET according to the present disclosure may be utilized to enhance device performance, scalability, and manufacturing efficiency in advanced semiconductor technologies.

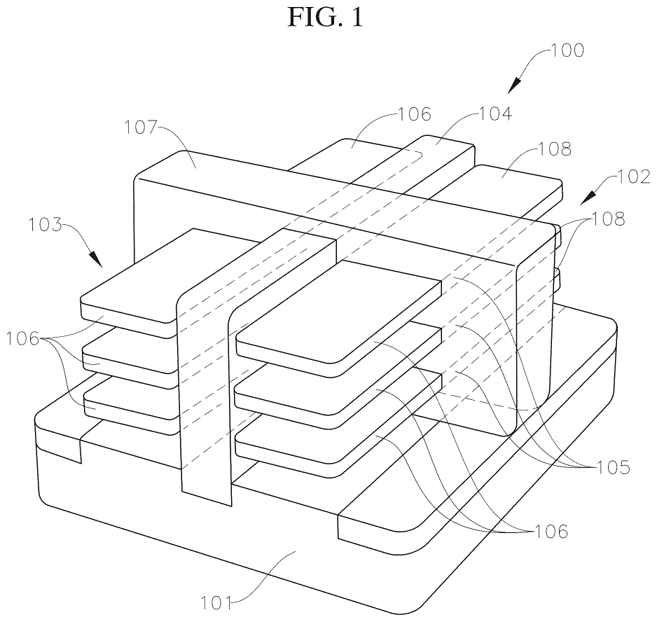

FIG. 1 depicts a forksheet field-effect transistor (FSFET) according to one embodiment of the present disclosure. In the illustrated embodiment, the FSFET 100 includes a substrate 101, an n-channel metal-oxide semiconductor (NMOS) transistor 102 and a p-channel metal-oxide semiconductor (PMOS) transistor 103 on the substrate 101, and a dielectric wall 104 separating the PMOS transistor 103 from the NMOS transistor 102. In the illustrated embodiment, the NMOS transistor 102 and the PMOS transistor 103 each include a plurality of stacked nanosheet channel regions 105, source/drain regions 106 at opposite ends of the nanosheet channel regions 105, and a gate 107 on the channel regions 105. Although in the illustrated embodiment the NMOS transistor 102 and the PMOS transistor 103 each include four nanosheet channel regions 105, in one or more embodiments the NMOS transistor 102 and the PMOS transistor 103 may include any other suitable number of stacked nanosheet channel regions 105, such as from two to six nanosheet channel regions 105. In one or more embodiments, the source/drain regions 105 are grown epitaxially in a lateral direction (laterally) away from the dielectric wall 104 (i.e., sideways epitaxy), as described in detail below. In one or more embodiments, due to the method of epitaxially growing the source/drain regions 105 described below, the source/drain regions 105 of the FSFET 100 may be free (or substantially free) of vertical stacking faults, which would otherwise reduce the channel stress and thereby negatively impact the performance of the FSFET.

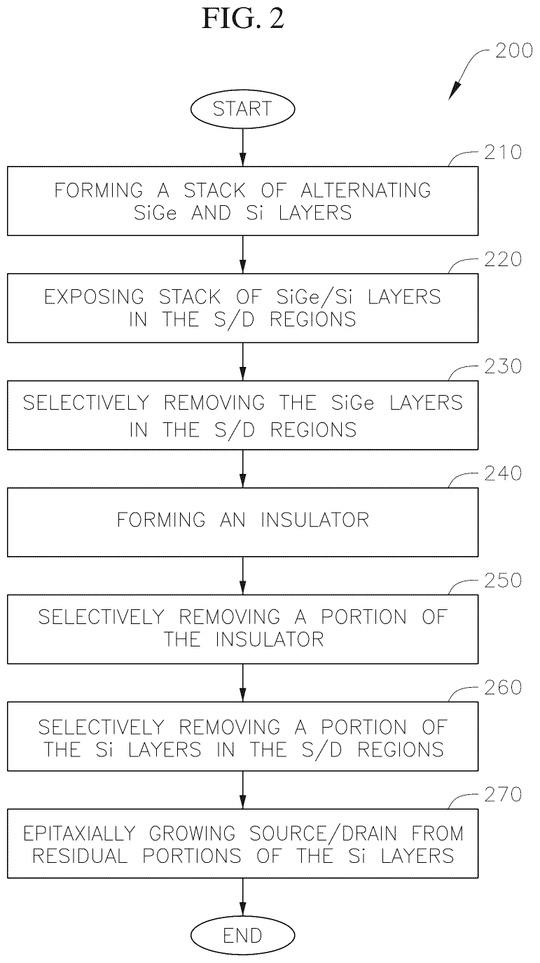

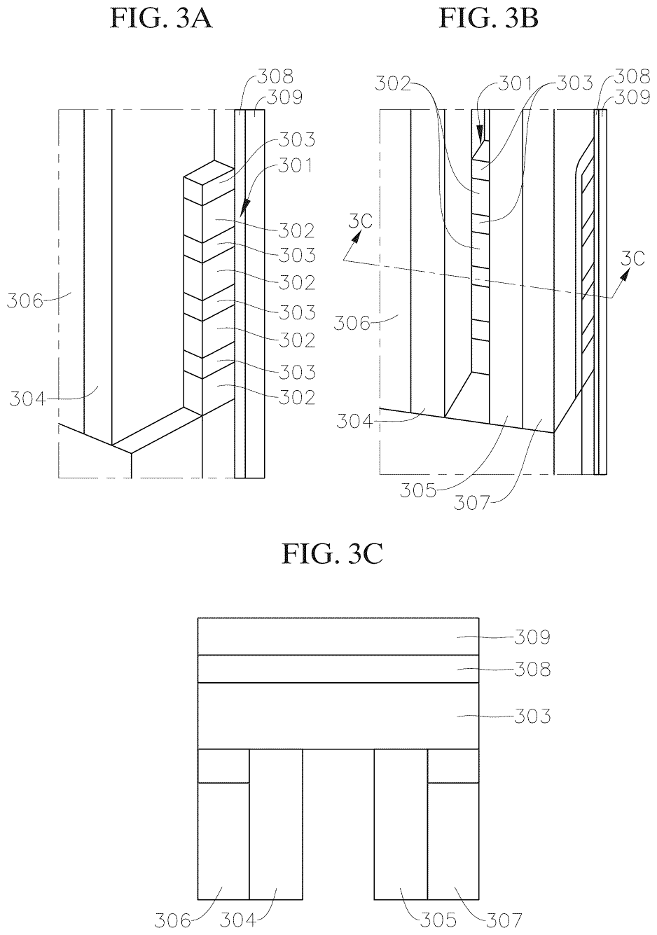

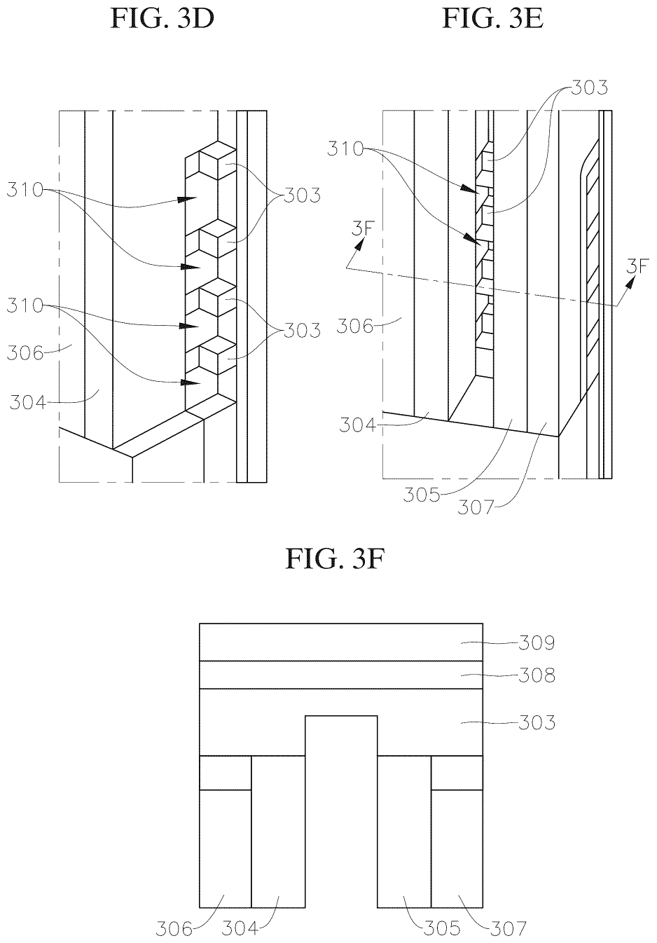

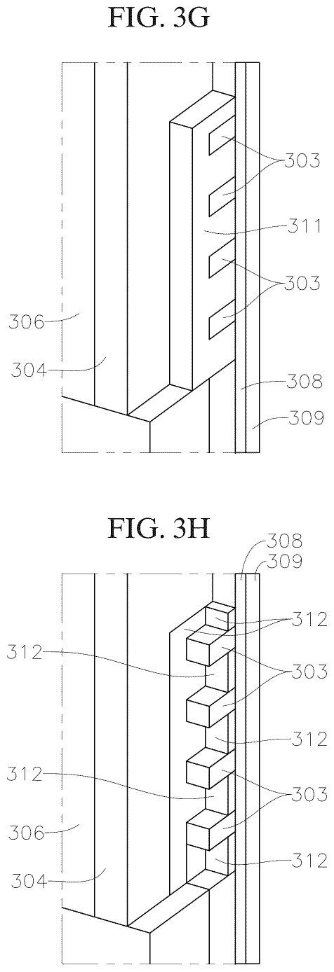

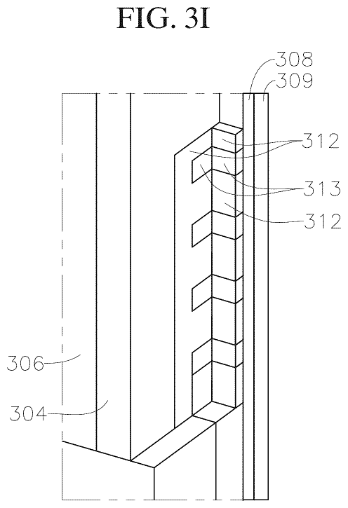

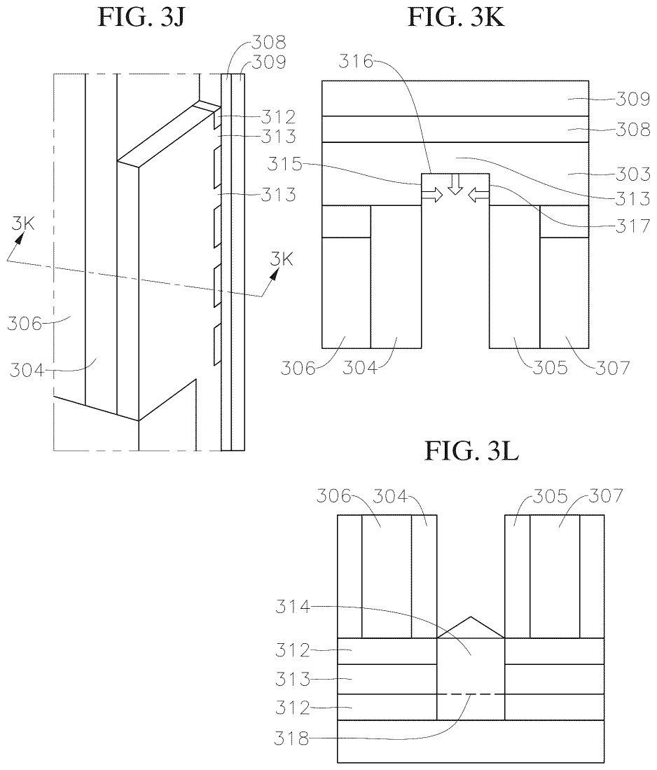

FIG. 2 depicts aspects of a method 200 of manufacturing a forksheet field-effect transistor (FET) (e.g., the FSFET 100 depicted in FIG. 1) according to one embodiment of the present disclosure, and FIGS. 3A-3L depict the structure of the forksheet FET 300 during the method 200 of manufacturing. Although FIG. 2 illustrates various operations in a method of manufacturing an FSFET, embodiments according to the present disclosure are not limited thereto, and according to various embodiments, the method may include additional operations or fewer operations, or the order of operations may vary, unless otherwise stated or implied, without departing from the spirit and scope of embodiments according to the present disclosure.

With reference now to FIGS. 2 and 3A-3C, the method 200 of manufacturing a forksheet field-effect transistor (FET) 300 according to one embodiment of the present disclosure includes a task 210 of forming a stack 301 of alternating silicon-germanium (SiGe) layers 302 and silicon (Si) layers 303. A pair of outer spacers 304, 305 may be formed such that they are spaced apart from each other on the stack 301 of alternating SiGe layers 302 and Si layers 303.

A pair of gates 306, 307 (e.g., polysilicon layers) may be formed outside of the pair of outer spacers 304, 305. A liner oxide layer 308 may be formed extending lengthwise along the stack 301 of alternating SiGe layers 302 and Si layers 303, and a sidewall 309 on the liner oxide layer 308. Together, the sidewall 309 and the liner oxide layer 308 form a dielectric wall.

FIG. 3A is a perspective view of half of the structure with the outer spacer 305 and the gate 307 not shown to reveal the structure of the alternating SiGe layers 302 and Si layers 303. FIG. 3B is a perspective view of the full structure showing both of the gates 306, 307 and both of the outer spacers 304, 305 formed outside the pair of spacers 304, 305 and over the stack 301. FIG. 3C is a cross-sectional taken along line C-C in FIG. 3B.

With continued reference to FIGS. 2 and 3A-3C, the method 200 includes a task 220 of exposing a portion of the stack 301 of alternating SiGe layers 302 and Si layers 303 in the source/drain regions of the forksheet FET 300. FIGS. 3A-3B depict the structure after the stack 301 has been exposed in the source/drain regions of the forksheet FET 300, for example, by removing (e.g., etching) one or more layers covering the stack 301 of alternating SiGe layers 302 and Si layers 303 in the source/drain regions.

With reference now to FIGS. 2 and 3D-3F, the method 200 also includes a task 230 of selectively removing (e.g., selectively etching) the SiGe layers 302 in the portion of the stack 301 of alternating SiGe layers 302 and Si layers 303 that are in the source/drain region that was exposed in task 220. Following task 230, voids or openings 310 are formed in the source/drain regions where the SiGe layers 302 were previously located. FIG. 3D is a perspective view of half of the structure; FIG. 3E is a perspective view of the full structure; and FIG. 3F is a cross-sectional taken along line F-F in FIG. 3E.

With reference now to FIGS. 2 and 3G, the method 200 also includes a task 240 of forming an insulator 311. The task 240 of forming the insulator 311 may include isotropic deposition of any suitable insulator material. Following task 240, the insulator 311 extends into the openings 310 formed in the task 230 of selectively removing the SiGe layers 302. In one or more embodiments, the insulator 311 also extends laterally outward beyond the Si layers 303 such that the insulator 311 is wider than the Si layers 303. Additionally, in one or more embodiments, the insulator 311 extends above the uppermost Si layer 303 (e.g., a portion of the insulator 311 formed in task 240 is on top of the uppermost Si layer 303).

With reference now to FIGS. 2 and 3H, the method 200 also includes a task 250 of selectively removing (e.g., selectively etching) a portion of the insulator 311 formed in task 240. Following task 250, portions 312 of the insulator 311 remain along the outer spacers 304, 305 and the liner oxide layer 308. In one or more embodiments, the task 250 of selectively removing a portion of the insulator 311 may utilize any suitable process, such as wet or dry etching. FIG. 3H is a perspective view of half of the FSFET structure and thus the portion 312 of the insulator 311 along the liner oxide layer 308 and one outer spacer 304 is shown but the portion of the insulator 311 along the other outer spacer 305 is omitted.

With reference now to FIGS. 2 and 3I, the method 200 also includes a task 260 of selectively removing a portion of each of the Si layers 303 in the source/drain region. Following task 260, a residual portion 313 of each of the Si layers 303 remains along the outer spacers 304, 305 and the liner oxide layer 308 in the source/drain region. Additionally, the residual portion 313 of each Si layer 303 is surrounded above and below by the portion 312 of the insulator 311 that remained following task 250. In one or more embodiments, the task 260 of selectively removing the portion of each of the Si layers 303 may be performed utilizing an anisotropic etch. In one or more embodiments, the task 260 includes selectively removing the Si layers 303 all the way (or substantially all the way) to the portion 312 of the insulator 311 that remained following task 250 such that the residual portion 313 of each of the Si layers 303 following task 260 has the same (or substantially the same) thickness as the portion 312 of the insulator 311 that remained following task 250. FIG. 3I is a perspective view of half of the FSFET structure and thus the residual portion 313 of the Si layers 303 along the liner oxide layer 308 and one outer spacer 304 is shown but the residual portion 313 of the Si layers 303 along the other outer spacer 305 is omitted.

With reference now to FIGS. 2 and 3J-3L, the method 200 also includes a task 270 of epitaxially growing source/drain regions 314 in a lateral direction (laterally) utilizing the residual portion 313 of the Si layers 303 as a seed for the epitaxial lateral growth (e.g., the residual portion 313 of the Si layers 303 functions as a continuous Si seed strip during the task 270 of epitaxially laterally growing the source/drain regions 314). As illustrated in FIG. 3K, during the task 270, the source/drain regions 314 epitaxially grow laterally from three different faces 315, 316, 317 of the residual portion 313 of the Si layers 303 (i.e., a first face 315 of the residual portion 313 of the Si layers 303 parallel (or substantially parallel) with a first one of the outer spacers 304, a second face 316 of the residual portion 313 of the Si layers 303 along the liner oxide layer 308, and a third face 317 of the residual portion 313 of the Si layers 303 parallel (or substantially parallel) with a second one of the outer spacers 305). In FIG. 3K, the arrows depict the direction of epitaxial growth of the source/drain regions 314. Epitaxially growing the source/drain regions 314 from the residual portion 313 of the Si layers 303 is configured to prevent (or at least mitigate) the formation of a vertical stacking fault in the source/drain regions 314, which would otherwise reduce channel stress and thereby negatively impact performance of the FSFET 300. In one or more embodiments, a lateral (horizontal) stacking fault 318 may be formed in the source/drain regions 314 (as shown in FIG. 3L), but lateral stacking faults (as opposed to vertical stacking faults) have a minimal (or nominal) impact on channel stress and therefore a minimal (or nominal) impact on the performance of the forksheet FET. Accordingly, in one or more embodiments, the FSFET 300 formed according to method 200 may be free (or substantially free) of vertical stacking faults in the source/drain regions 314. In contrast, in a related art method of manufacturing a FSFET, the Si layers in the source/drain regions may be completely removed such that the source/drain regions are epitaxially grown only from two opposing faces of the Si layers, which results in a vertical stacking fault that negatively impacts the channel stress of the FSFET, as described in more detail below.

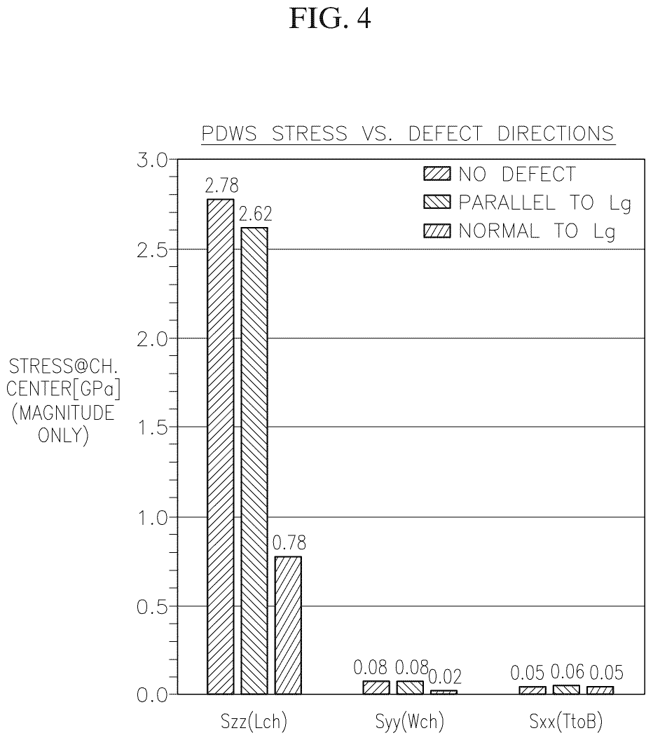

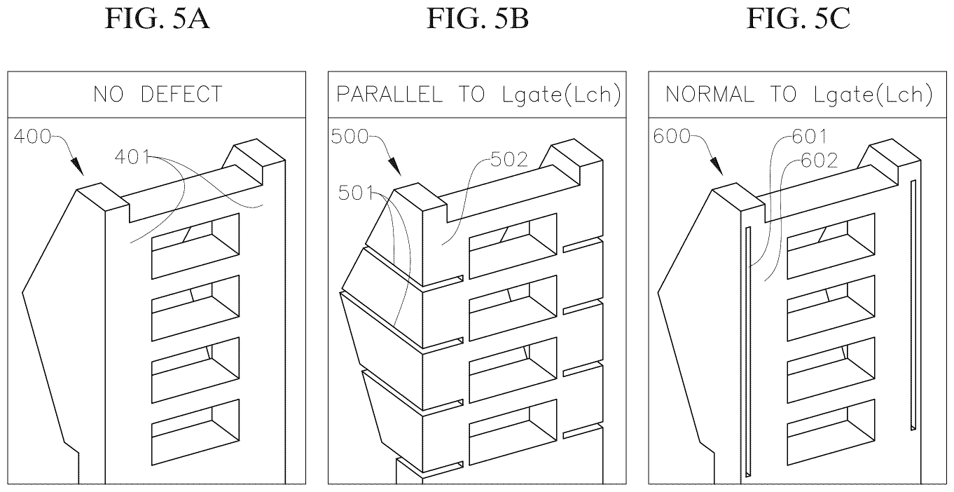

FIG. 4 is a graph showing the channel stress in a forksheet field-effect transistor (FSFET) as a function of the direction of the defect in the source/drain regions. FIG. 4 compares the channel stress at the channel center in gigapascals (GPa) in a forksheet field-effect transistor (FSFET) having a horizontal fault in the source/drain region (labeled as “Parallel to Lg”), a FSFET having a vertical fault in the source/drain region (labeled as “Normal to Lg”), and a FSFET having no fault in the source/drain region (labeled as “No defect”). The graph depicts the channel stress along the channel length (labeled “Szz(Lch)”), the channel stress along the channel width (labeled “Syy(Wch)”), and the channel stress in the thickness (top-to-bottom) direction (labeled “Sxx(TtoB)”). This graph was generated by modeling a FSFET 400 having no defect in the source/drain regions 401, a FSFET 500 having horizontal (lateral) defects 501 in the source/drain regions 502 that are parallel to the Lgate (Lch), and a FSFET 600 having vertical defects 601 in the source/drain regions 602 that are normal (perpendicular) to the Lgate (Lch) as shown in FIGS. 5A-5C, respectively. As illustrated in FIG. 4, the FSFET 400 having no defects in the source/drain regions has a channel stress at channel center and along the channel length direction (“Szz(Lch)”) of approximately 2.78 GPa, the FSFET 500 having a horizontal (lateral) stacking fault in the source/drain regions has a channel stress at channel center of approximately 2.62 GPa, and the FSFET 600 having a vertical stacking fault in the source/drain regions has a channel stress at channel center of approximately 0.78 GPa. Accordingly, the FSFET according to various embodiments of the present disclosure having a horizontal stacking fault (but no vertical stacking fault) in the source/drain regions has substantially the same channel stress as an idealized FSFET with no defects or stacking faults (i.e., the FSFET according to one embodiment of the present disclosure having a horizontal stacking fault, but no vertical stacking fault, in the source/drain regions has a channel stress that is approximately 94% of the channel stress as an idealized FSFET with no defects or stacking faults), which improves performance of the FSFET. In contrast, the FSFET manufactured according to the related art method, which includes a vertical stacking fault in the source/drain regions, has a channel stress that is only approximately 28% of the channel stress as the idealized FSFET with defects or stacking faults, which degrades the performance of the FSFET.

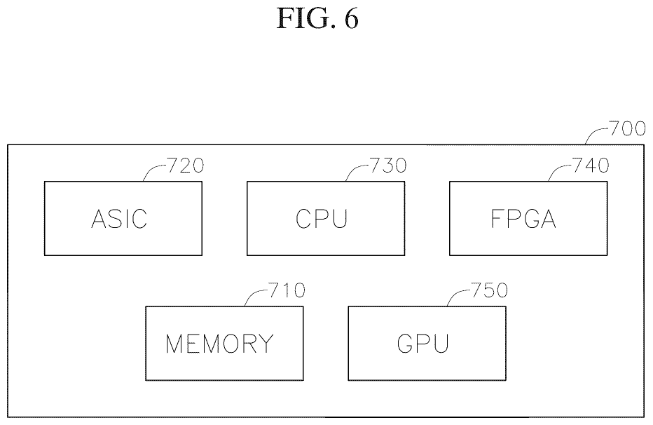

FIG. 6 depicts an electronic device 700 including a forksheet field-effect transistor (FSFET) (e.g., the FSFET 100 of FIG. 1 or the FSFET manufactured according to the method 200 of FIG. 2) according to one embodiment of the present disclosure. Referring to FIG. 6, the electronic device 700 may include at least one of a memory 710, an application specific integrated circuit (ASIC) 720, a central processing unit (CPU) 730, a field programmable gate array (FPGA) 740, or a graphics processing unit (GPU) 750. The FSFET may be included in any one of the memory 710, the ASIC 720, the CPU 730, the FPGA 740, and/or the GPU 750.

The electronic device 700 may be a stand-alone system that uses the FSFET to perform one or more electrical functions. Alternatively, the electronic device 700 may be a subcomponent of a larger system. For example, the electronic device 700 may be part of a computer (e.g., a desktop computer, a laptop computer, or a tablet computer), a cellular phone (e.g., a smart phone), a personal digital assistant (PDA), a digital video camera (DVC), or other electronic communication device. Alternatively, the electronic device 700 may be the memory 710, the ASIC 720, the CPU 730, the FPGA 740, the GPU 750, a network interface card, or other signal processing card that can be inserted or included in a computer or other larger system.

The electronic device and/or the FSFET according to embodiments of the present disclosure may be incorporated or implemented in any suitable hardware, for example, a flexible printed circuit film, a tape carrier package (TCP), a printed circuit board (PCB), combinational logic, sequential logic, timers, counters, registers, state machines, volatile memories such as dynamic RAM (DRAM) and/or static RAM (SRAM), nonvolatile memory including flash memory (e.g., not-AND (NAND) flash memory), persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application-specific ICs (ASICs), central processing units (CPUs) including complex instruction set computer (CISC) processors and/or reduced instruction set computer (RISC) processors, graphics processing units (GPUs), neural processing units (NPUs), tensor processing units (TPUs), data processing units (DPUs). Also, a person of skill in the art should recognize that the electronic device and/or the FSFET may be combined or integrated into a single computing device, or the electronic device and/or the FSFETs may be distributed across one or more other computing devices without departing from the spirit and scope of the embodiments of the present disclosure. For instance, in some embodiments, the electronic device and/or the FSFET may be on one integrated circuit (IC) chip or on separate IC chips. In some embodiments, the electronic device and/or the FSFET may be implemented as a system-on-a-chip (SoC).

In some embodiments, the electronic device and/or the FSFET may be implemented entirely or partially with, and/or used in connection with, a server chassis, server rack, data room, data center, edge data center, mobile edge data center, and/or any combinations thereof.

The electronic device according to embodiments of the present disclosure may include a communication connection and/or a communication interface for communicating with one or more other devices via any suitable type of communication protocol. Examples include Peripheral Component Interconnect Express (PCIe), non-volatile memory express (NVMe), NVMe-over-fabric (NVMe-oF), Ethernet, Transmission Control Protocol/Internet Protocol (TCP/IP), Direct Memory Access (DMA) Remote DMA (RDMA), RDMA over Converged Ethernet (ROCE), FibreChannel, InfiniBand, SATA, SCSI, SAS, Internet Wide Area RDMA Protocol (iWARP), and/or a coherent protocol, such as Compute Express Link (CXL), CXL.mem, CXL.cache, CXL.IO and/or the like, Gen-Z, Open Coherent Accelerator Processor Interface (OpenCAPI), Cache Coherent Interconnect for Accelerators (CCIX), and/or the like, Advanced eXtensible Interface (AXI), any generation of wireless network including 2G, 3G, 4G, 5G, 6G, and/or the like, any generation of Wi-Fi, Bluetooth, near-field communication (NFC), and/or the like, or any combination thereof.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A method of manufacturing a forksheet field-effect transistor (FSFET), the method comprising:
exposing a stack of alternating silicon layers and silicon-germanium (SiGe) layers in source/drain regions of the FSFET between a pair of outer spacers;
selectively removing the SiGe layers in the source/drain regions of the FSFET to form a plurality of voids;
depositing an insulator in the plurality of voids previously occupied by the SiGe layers;
partially etching the insulator, wherein a portion of the insulator remains between each of the silicon layers following the partially etching;
partially etching the silicon layers, wherein a residual portion of the silicon layers remains following the partially etching; and
epitaxially growing, in a lateral direction, the source/drain regions of the FSFET from the residual portion of silicon layers, the residual portion of the silicon layers being a seed for the epitaxially growing of the source/drain regions.

2. The method of claim 1, wherein the depositing comprises isotropically depositing the insulator.

3. The method of claim 1, wherein the partially etching comprises isotropically etching the insulator.

4. The method of claim 1, wherein the source/drain regions are free from a vertical stacking fault.

5. The method of claim 4, wherein the source/drain regions comprise a horizontal stacking fault.

6. The method of claim 1, wherein the source/drain are formed continuously during the epitaxially growing of the source/drain regions.

7. The method of claim 1, wherein the epitaxially growing the source/drain regions comprises epitaxially growing the source/drain regions from three different faces of the residual portion of the silicon layers.

8. The method of claim 7, wherein the three different faces include a first face of the residual portion of the silicon layers between the pair of outer spacers, a second face of the residual portion of the silicon layers substantially parallel with a first outer spacer of the pair of outer spacers, and a third face of the residual portion of the silicon layers substantially parallel with a second outer spacer of the pair of outer spacers.

9. A method of manufacturing a forksheet field-effect transistor (FSFET), the method comprising:
forming a stack of alternating silicon layers and silicon-germanium (SiGe) layers on a substrate;
forming a plurality of gates on the stack of alternating silicon layers and SiGe layers;
forming a plurality of outer spacers on the stack of alternating silicon layers and SiGe layers;
forming a liner oxide layer along a lengthwise direction of the stack of alternating Si layers and SiGe layers;
forming a sidewall on the liner oxide layer;
selectively removing the SiGe layers in source/drain regions of the FSFET to form a plurality of voids;
depositing an insulator in the plurality of voids previously occupied by the SiGe layers;
partially etching the insulator, wherein a portion of the insulator remains between each of the silicon layers following the partially etching;
partially etching the silicon layers, wherein a residual portion of the silicon layers remains following the partially etching; and
epitaxially growing, in a lateral direction, the source/drain regions of the FSFET from the residual portion of the silicon layers, the residual portion of the silicon layers being a seed for the epitaxially growing of the source/drain regions.

10. The method of claim 9, wherein the depositing comprises isotropically depositing the insulator.

11. The method of claim 9, wherein the partially etching comprises isotropically etching the insulator.

12. The method of claim 9, wherein the source/drain regions are free from a vertical stacking fault.

13. The method of claim 12, wherein the source/drain regions comprise a horizontal stacking fault.

14. The method of claim 9, wherein the source/drain are formed continuously during the epitaxially growing the source/drain regions.

15. The method of claim 9, wherein the epitaxially growing the source/drain regions comprises epitaxially growing the source/drain regions from three different faces of the residual portion of the silicon layers.

16. The method of claim 15, wherein the three different faces include a first face of the residual portion of the silicon layers between a pair of outer spacers of the plurality of outer spacers, a second face of the residual portion of the silicon layers substantially coplanar with a first outer spacer of the pair of outer spacers, and a third face of the residual portion of the silicon layers substantially coplanar with a second outer spacer of the pair of outer spacers.

17. A forksheet field-effect transistor comprising:
a substrate;
an n-channel metal-oxide semiconductor (NMOS) transistor on the substrate;
a p-channel metal-oxide semiconductor (PMOS) transistor on the substrate; and
a dielectric wall separating the PMOS transistor from the NMOS transistor,
wherein each of the NMOS transistor and the PMOS transistor comprises a plurality of stacked nanosheet channel regions, source/drain regions at opposite ends of the nanosheet channel regions, and a gate on the nanosheet channel regions, and
wherein the source/drain regions are substantially free from a vertical stacking fault.

18. The forksheet field-effect transistor of claim 17, wherein the source/drain regions comprise a horizontal stacking fault.

19. The forksheet field-effect transistor of claim 17, wherein each of the PMOS transistor and the NMOS transistor further comprises a pair of outer spacers.

20. The forksheet field-effect transistor of claim 17, wherein the dielectric wall comprises a sidewall and a liner oxide layer on the sidewall.
